(19) United States
(12) Patent Application Publication
(10) Pub. No.: US 2023/0307168 A1
(43) Pub. Date: Sep. 28, 2023

(54) STACKABLE COMPONENTS FOR STATIONARY ENERGY STORAGE SYSTEMS

(71) Applicant: Mitsubishi Power Americas, Inc., Lake Mary, FL (US)

(72) Inventors: Craig Satoshi Brooker, Winter Springs, FL (US); Michael Thomas Leonard, South Park, PA (US); Michael McManus, Winter Springs, FL (US); Minesh Patel, Oviedo, FL (US)

(21) Appl. No.: 17/705,655

(22) Filed: Mar. 28, 2022

(51) Int. Cl. H01F 27/06; H02J 3/32

(52) U.S. Cl. CPC H01F 27/06; H02J 3/32

(57) ABSTRACT

A battery energy storage system comprises a first equipment unit comprising a first skid positionable on a surface, a first inverter and a first transformer mounted on the first skid, a second equipment unit comprising a second skid, a second inverter and a second transformer mounted on the second skid, and a support structure for positioning the second equipment unit longitudinally above and spaced apart from the first equipment unit in a laterally offset manner. A method of increasing energy storage capacity of a storage system comprises building a support structure over a first inverter and transformer unit installed at a first location, placing a second inverter and transformer unit on the support structure such that the second inverter and transformer unit is longitudinally spaced from and laterally offset from the first inverter and transformer unit and adding an additional battery container.

### TECHNICAL FIELD

The present application pertains generally, but not by way of limitation, to distributed grid networks that provide electricity from power producers to end users. More specifically, but not by way of limitation, the present application relates to stationary energy storage systems that can be used to store electrical power from a distributed grid network (“the grid”).

### BACKGROUND

Power plants typically supply power to the grid within a distributed network where voltage is provided at a constant amplitude or magnitude and frequency is maintained at a certain value within limits. As such, electrical power can be provided to end users in a consistent format. When the demand on the grid changes sufficiently, it can be desirable to bring additional power producers online or have power producers go offline or into a standby mode in order to more closely match production with demand.

In order to more smoothly match power production with power demand, stationery energy storage systems can be used to store excess power generated by the producers or provide power to the grid to meet excess demand from the end users. Examples, of typical stationary energy storage systems comprise Battery Energy Storage Systems (BESSs). A BESS can utilize large scale rechargeable batteries that are configured for operation with the grid. Connection of the batteries of BESSs to the grid can involve the use of larges-scale electrical equipment, such as inverters and transformers, in order to match the stored power of the batteries to useable power on the grid.

Examples of gas turbine engine systems using inverters or converters are described in Pub. No. WO/2021/058832 to Moodie; Pub. No. WO12012/118491 to Saab; and Pat. No. EP 3070819 B1 to Brewer et al.

### OVERVIEW

The present inventors have recognized, among other things, that problems to be solved in stationary battery energy storage systems include the increasing scarcity of space available for building stationary battery energy storage systems such as BESSs. For example, BESSs are often constructed in rural areas where they can be connected to the grid in wide open spaces and out of sight a large portion of the population. However, with the recent increase in the use of renewable energy sources such as wind and solar that provide intermittent power supply, there has been a greater need for increasing the storage capacity of existing BESSs where space is already occupied with batteries and electrical equipment. Furthermore, the demand for renewable energy has further pushed the need to add stationary battery energy storage capacity in urban areas where space is limited.

Conventional stationary battery energy storage facilities utilize electrical equipment mounted onto slabs or into shipping containers that are placed in a pattern to facilitate access to various control panels and the like. While these arrangements provide facilities that are easy to maintain and safe due to the spacing between equipment, they do not allow for a high density of equipment to be placed in a fixed amount of space. For example, the use of shipping containers to store electrical equipment poses constraints on providing maintenance to the electrical equipment due to the closed-in nature of the containers. Additionally, the closed-in nature of the shipping containers can require the use of cooling and ventilating equipment to keep the electrical equipment operating at desirable temperatures.

The present subject matter can provide solutions to these problems and other problems, such as by providing methods and systems for configuring stationary battery energy storage facilities to have stacked electrical equipment, including inverters and transformers. The stacked electrical equipment can utilize skids that allow the electrical equipment to be elevated with support structure that can surround ground-level electrical equipment. The skids can include passages to allow for passage of electrical connectors and cable to pass through the skids. The ground-level and elevated skids can be laterally offset so that the top of ground-level equipment and the side of elevated equipment can be accessed from the top of a platform, and the bottom of elevated equipment and side of ground-level equipment can be accessed from below the platform. The ground-level skids and elevated skids can additionally be longitudinally offset to provide space between the stacked electrical equipment to, for example, facilitate running of cables, provide heat dissipation and the like. The support structure can be constructed to allow for climbing equipment, such as ladders, and safety equipment, such as railings. Furthermore, the support structure can be constructed to absorb energy from an arc flash event or the release of a blowout panel.

A battery energy storage system (BESS) can comprise a first equipment unit comprising a first skid configured to be positioned on a surface, a first inverter mounted on the first skid and a first transformer mounted on the first skid, a second equipment unit comprising a second skid, a second inverter mounted on the second skid and a second transformer mounted on the second skid, and a support structure for positioning the second equipment unit longitudinally above and spaced apart from the first equipment unit in a laterally offset manner.

A method of increasing energy storage capacity of a Battery Energy Storage System (BESS) can comprise building a support structure over a first inverter and transformer unit installed at a first location of the BESS, placing a second inverter and transformer unit on the support structure such that the second inverter and transformer unit is longitudinally spaced from and laterally offset from the first inverter and transformer unit and adding an additional battery container to the BESS.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

FIG. 1 is a schematic diagram of a power system illustrating multiple power plants and a battery electric storage system (BESS) configured to provide electrical power to end users of a distributed grid network (DGN) or “grid.”

FIG. 2A is a schematic diagram illustrating a conventional arrangement of BESS containers relative to inverters and transformers used to process the electrical energy stored in the BESS containers.

FIG. 2B is a schematic diagram illustrating an arrangement of the present disclosure utilizing stacked inverters and transformers positioned relative to BESS containers.

FIG. 3A is a schematic diagram illustrating a front view of stacked skids that each have an inverter and a transformer.

FIG. 3B is a schematic diagram illustrating a side view of the stacked skids of FIG. 3A showing an offset arrangement.

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

### DETAILED DESCRIPTION

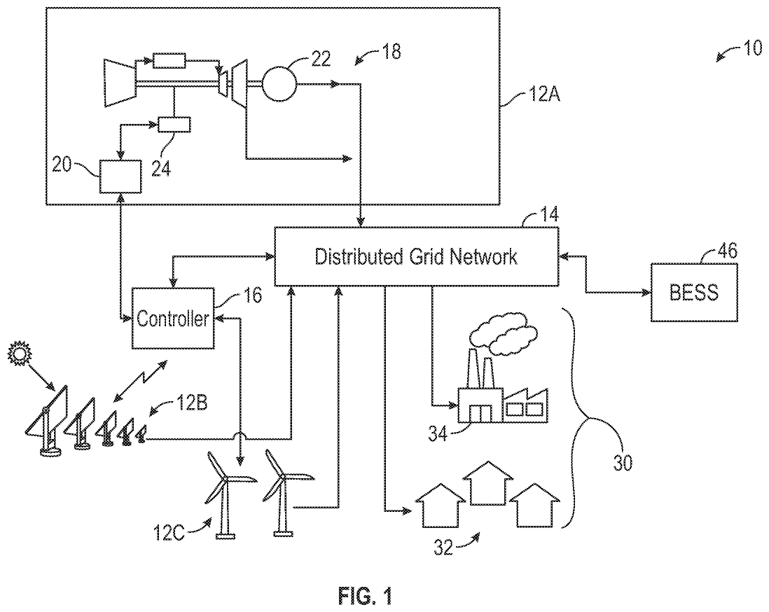

FIG. 1 is a schematic diagram of power system 10 illustrating power plants 12A, 12B, and 12C providing electrical power to distributed grid network (DGN) or “grid” 14, which can include controller 16. Power plant 12A can include generator unit 18 and controller 20. Generator unit 18 can comprise electrical generator 22, engine controller 24, such as a Distributed Control Systems (DCS) device, and gas turbine 26. Grid 14 can be configured to deliver power from electrical generator 22, as well as power from power plants 12B and 12C, to end users 30, which can include residential housing units 32 and factory 34, for example.

Power plants 12A, 12B and 12C can comprise the same or different types of power plants. In examples, power plant 12A may be a gas turbine power plant and power plants 12B and 12C can comprise renewable energy resources, such as wind and solar. Battery Energy Storage System (BESS) 46 can additionally be connected to grid 14. As discussed herein, BESS 46 can store excess power from grid 14 and release power to grid 14 to accommodate supply and demand differences between power plants 12A-12C and end users 30.

Controller 20 can cooperate with each of the power plants 12A 12C to balance power supply with power demand. It will be appreciated that gas turbine power plants, such as power plant 12A are typically configured to operate most efficiently at or near maximum output. As such, there can be inefficiencies in starting, stopping and changing operation of power plant 12A.

In examples, controller 16 or controller 20 can be connected to BESS 46 to control operation of BESS 46. For example, controller 16 can be configured to put BESS 46 into charge modes when grid 14 is producing excess power and to put BESS 46 into discharge modes when grid 14 is operating at a deficit of power. Additionally, controller 20 can be configured to operate BESS 46 to capture energy produced by generator unit 18 that is not needed by grid 14 in order to reduce the need for operating gas turbine 26 at inefficient operating states.

In general, due to differing demand levels from end users 30, the amount of electricity available from grid 14 can vary. In times of high demand, it can be useful to have all of power plants 12A, 12B and 12C producing power. In times of low demand, it can be useful to have less than all of power plants 12, 12B and 12C producing. However, it is not always easy or efficient to have the output of power plants 12A-12C match the demand from end users 30.

BESS 46 can be configured to provide power to and receive power from grid 14. When demand on grid 14 is low, producers 12A 12C connected to grid 14 can have excess energy production capabilities. It can be advantageous to store the energy generated by producers 12A-12C at BESS 46. For example, it can be more efficient to continue to produce energy and store the excess energy than to shut down or ramp down production, particularly at gas turbine combined cycle (GTCC) power production facilities where performance or emissions may be negatively impacted by ramping down operation of gas turbine engines. Additionally, producers 12A 12C that take advantage of renewable energy sources, such as wind and solar, can store power generated by these methods when environmental conditions are favorable for wind and solar energy production for later use when environmental conditions are unfavorable for wind and solar energy production. When demand on grid 14 is high, energy stored in BESS 46 can be discharged to grid 14. BESS 46 can, therefore, smooth out changes in demand for electricity relative to power producers, such as by providing time for additional energy producers to come online or currently producing energy producers to ramp up output.

As mentioned, grid 14 can be distributed over a wide geographic area. As such, BESS 46 can be located where space is available. Sometimes it is desirable to add capacity to BESS 46 in geographic locations where additional space is not available for expanding the footprint of BESS 46. With the present disclosure, the capacity or energy density of BESS 46 can be increased by stacking components of BESS 46 longitudinally to eliminate having to increase the footprint or occupied geographic area of BESS 46.

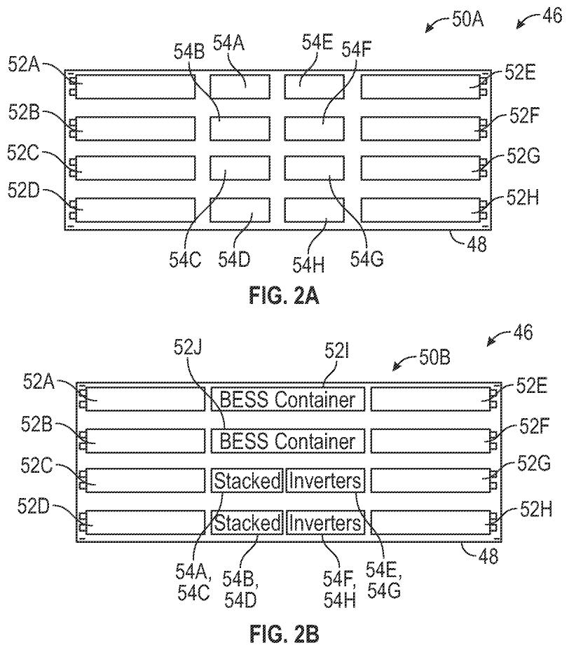

FIG. 2A is a schematic diagram illustrating a conventional arrangement 50A of BESS 46 of FIG. 1. Conventional arrangement 50A can comprise BESS containers 52A 52H arranged relative to electric equipment skids 54A-54G in a single level within perimeter or footprint 48. Each of BESS containers 52A 52H can comprise one or more battery cells configured to store electrical power. Each of electrical equipment skids 54A-54G can comprise an inverter and a transformer mounted on a platform comprising a skid. Electrical equipment skids 54A-54G can be configured to electrically condition the differing power requirements (such as voltage, current, and frequency) of the grid and/or BESS containers for interaction therebetween.

BESS containers 52A-52H can comprise a plurality of individual batteries arranged in packs. Each of the individual batteries can be configured as a rechargeable battery configured to store electrical power that can be provided to grid 14 upon appropriate demand levels, Batteries of BESS containers 52A 52H can utilize different technologies, including Lithium-ion (Li-ion), lead-acid, nickel-cadmium, nickel-metal-hydride, and sodium-sulfur. However, newly constructed stationary energy storage facilities typically use the same technology for all the batteries in the numerous battery packs in order to simplify the construction and standardize the control operations for each battery and battery pack. Battery cells of BF SS containers 52A 52H can be arranged in shipping containers and can thus have elongate rectangular footprints. One end of the container typically includes all of the connectors for delivering power to and receiving power from the battery cells. As such, electrical equipment skids 54A 54G can be positioned centrally between BESS containers 52A-52H to allow electrical equipment skids 54A 54G to be brought to a common point of interconnect (POI) to grid 14.

BESS containers 52A-52H and electric equipment skids 54A-54G FIG. 2B can be arranged in a grid pattern with columns of electric equipment skids 54A 54G disposed between columns of BESS containers 52A-52H. In such an arrangement, electric equipment skids 54A-54G can be centrally located to facilitate connection to grid 14. Additionally, the grid of columns and rows can provide spacing that forms aisles to allow personnel to move between units and open access panels on BESS containers 52A-52H and electric equipment skids 54A-54G.

Often times, stationary battery energy storage facilities are configured so there is a one-to-one correspondence between BESS containers and electrical equipment skids. As such, increasing the storage capacity of a BESS can involve adding additional BESS containers 52A-52H and electric equipment skids 54A-54G as needed. In many situations, space can be readily available to increase the capacity of BESS 46 by adding more BESS containers 52A-52H and electric equipment skids 54A-54G. As such, the capacity of BESS 46 can be proportional to the square footage of space occupied by BESS 46. However, as power producers are having to adjust to more and more space constraints due to increased use of intermittent renewal energy, sources and increased usage in urban areas, simply building out stationary energy storage facilities to occupy larger spaces with the same equipment density is untenable. With the systems and methods of the present disclosure, the equipment density of stationary energy storage facilities

FIG. 2B is a schematic diagram illustrating stacked arrangement 50B of BESS 46 of FIG. 1. Stacked arrangement SOB of the present disclosure can comprise stacked and offset equipment skids 54A-54G arranged relative to BESS containers 52A-52H within perimeter of footprint 48. In stacked arrangement 50B, the same number of electric equipment skids 54A-54G as conventional arrangement 50A of NG. 2A are used with the addition of two more BESS containers 52I and 52J without increasing the square footage or rectangular footprint of stationary energy storage facility 46.

As mentioned, it can be expedient to design new BESS facilities to have a one-to-one correspondence between BESS containers and electrical equipment skids and to upscale a BESS by adding one new electrical equipment skid per BESS container that are of the same types as the originally installed equipment to upgrade capacity when space is available. However, when space, e.g, the square measure of the footprint of a BESS facility, is not available, choices between adding and replacing equipment can be made. The present inventors have determined that it can be less expensive to add additional BESS containers and upgrade or change the electrical equipment skids with higher capacity inverters and transformers, if needed. As such, in the present disclosure, additional BESS containers 52I and 52J can be added to BESS containers 52A-52H for use with the same electrical equipment skids 54A-54G or by upgrading electrical equipment skids 54A-54G to operate with a larger capacity of battery storage. The present inventors have recognized that additional BESS containers 52I and 52J can be added by stacking electrical equipment skids 54A-54G to avoid increasing the space or footprint occupied by BESS 46, The present disclosure can facilitate stacking of inverters and transformers in a safe and practical manner thereby freeing space for additional BESS containers 52I and 52J and without having to stack any of BESS containers 52A— 52H, which can weigh much more than electrical equipment skids 54A 5411. Inverters and transformers of the present disclosure can weigh on the order of approximately forty thousand pounds or approximately eighteen thousand kilograms. Furthermore, the footprints of BESS containers 52A 52H is larger than the footprints of electrical equipment skids 54A-54H, making stacking more difficult.

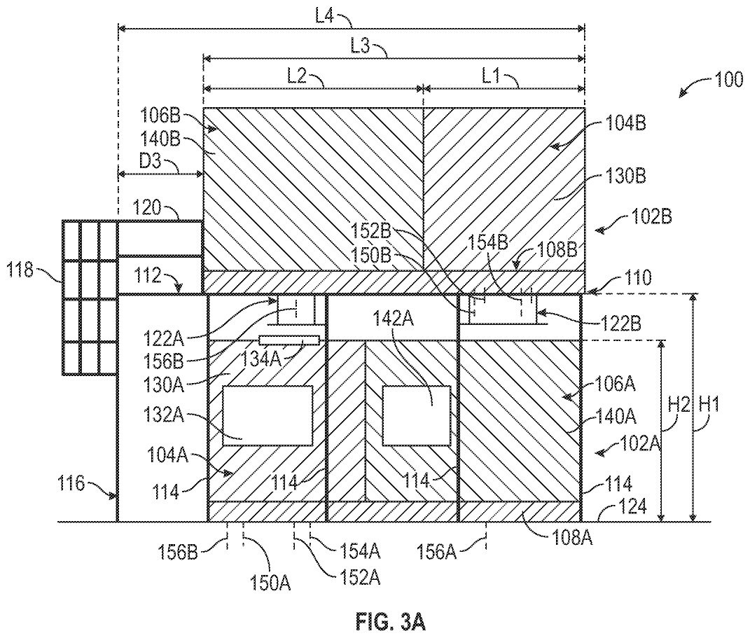

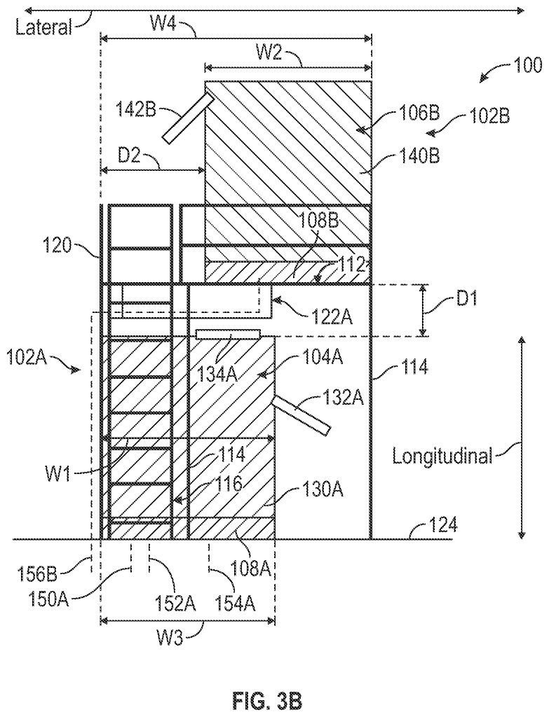

As discussed with reference to FIGS. 3A and 3B, stacked arrangement 50B can utilize a support structure to elevate some of equipment skids 54A-54G relative to each other, thereby permitting the inclusion of additional BESS containers. As such, the energy storage capacity of BESS 46 can be increased by increasing the equipment density within footprint 48 without increasing the area of footprint 48.

FIG. 3A is a schematic diagram illustrating a front view of stacked skids unit 100 comprising lower skid unit 102A and upper skid unit 102B showing a longitudinally offset arrangement. FIG. 3B is a schematic diagram illustrating a side view of stacked skids unit 100 of FIG. 3A showing a laterally offset arrangement. FIGS. 3A and 3B are discussed concurrently.

Lower skid unit 102A can comprise first inverter 104A, first transformer 106A and first skid 108A. Upper skid unit 102B can comprise second inverter 104B, second transformer 106B and second skid 108B. Stacked skids unit 100 can further comprise support structure 110, which can comprise platform 112, posts 114, ladder 116, cage 118, railing 120, first cable raceway 122A and second cable raceway 122B.

Surface 124 can comprise an outdoor ground surface or an indoor floor surface. Surface 124 can comprise dirt, gravel, cement, asphalt, concrete, pavement, and the like. Surface 124 can be coated and painted as desired to provide, for example, insulating properties and moisture resistance. Surface 124 can be flat such that first skid 108A and posts 114 can engage surface 124 flush, Surface 124 can be level such that all points of the upper surface of first skid 108A are generally at the same grade and all lower ends of posts 114 are at the same grade.

Inverters 104A and 104B can have length L1 (FIG. 3A) and width W1 (FIG. 3B).

Transformers 106A and 106B can have length L2 (FIG. 3A) and width W2 (FIG. 3B).

Skids 108A and 108B can have length L3 (FIG. 3A) and width W3 (FIG. 3B).

Platform 112 can have length L4 (FIG. 3A) and width W4 (FIG. 3B).

The maximum height of inverter 104A and transformer 106A as placed on top of skid 108A can be H1.

Platform 112 can be located at a height H2 above surface 124.

Platform 112 can be separated from the tops of inverter 104A and transformer 106A by distance D1.

L1 can equal W1 and W1, W2 and W3 can b equal to each other.

Width W4 can be wider than width W2 by distance D2.

Length L4 can be wider than length. L3 by distance D3.

First skid 108A can comprise a platform upon which both of first inverter 104A and first transformer 106A can be positioned. First skid 108A can comprise a steel frame or other structure that can facilitate being engaged with or picked up by lifting equipment, such as a forklift or a crane, as well as providing structural support for the equipment in which it bears. First skid 108A can comprise a hollow structure having channels or tunnels into which forklift blades or lifting straps can be inserted. The hollow structure can also provide space for positioning of cables (e.g., cables 150A-156A) extending from bottom sides of first inverter 104A and first transformer 106A.

First skid 108A can be rectilinear in shape. In examples, the footprint of first skid 108A relative to surface 124 can have width W3 and length L3. First skid 108A can have a rectangular footprint configured to receive first inverter 104A and first transformer 106A. In examples, length L3 can be approximately equal to the sum of length L1 and length L2 and width W3 can be approximately equal to width W2 and width W1. As such, first skid 108A can have a footprint that is approximately the same size as the combined footprints of first inverter 104A and first transformer 106A.

Inverter 104A can comprise a system or device for receiving the output of one of BESS containers 52A-52J (FIG. 3B). Inverter 104A can convert between different types of current, such as direct current (DC) and alternating current (AC). In typical grid systems, BESS containers 52A-52J can provide DC power and grid 14 can operate with AC power. As such, inverter 104A can be configured to convert DC power from BESS containers 52A-52J to AC power for grid 14, and vice versa, depending on whether BESS containers 52A-52J are discharging or charging. Inverter 104A can additionally scale the current level, e.g., the Amperes, appropriately between BESS containers 52A 52J and grid 14.

Inverter 104A can comprise housing 130A into which the components performing the electrical capabilities are disposed. Housing 130A can define the outer shape of inverter 104A. Housing 130A can comprise a cabinet having one or more of panel 132A configured to provide access to the interior of housing 130A. Panel 132A can be configured as a door that can swing open away from housing 130A along a hinge. Housing 130A can further comprise blowout panel 134A, Blowout panel 134A can be positioned on a top side of housing 130A and can be configured to allow for the release of energy from inverter equipment inside housing 130A in a controlled manner in a controlled direction. Thus, in the event of failure of the inverter equipment inside housing 130A that might cause an explosion, energy from the explosion can be directed into blowout panel 134A, which can then become dislodged, to disperse the energy upward and away from personnel standing alongside inverter 104A. Housing 130A can have a cuboid or rectangular cuboid shape. Housing 130A can have a width axis equal to width W1 and a length axis equal to L1. In the illustrated example, housing 130A has a square width and length footprint with width W1 and length L1 being equal.

Transformer (XMFR) 106A can comprise a device or system for transforming the voltages between BESS containers 52A 52J and grid 14. For example, transformer 106A can step-up or step-down the voltages between BESS containers 52A-52J and grid N. In examples, transformer 106A can step-down the voltage to BESS containers 52A 52J, and vice versa.

Transformer 106A can comprise housing 140A into which the components performing the voltage changes are disposed. Housing 140A can define the outer shape of transformer 106A, Housing 140A can comprise a cabinet having one or more of panel 142A configured to provide access to the interior of housing 140A. Panel 142A can be configured as a door that can swing open away from housing 140A along a hinge. Housing 140A can have a cuboid or rectangular cuboid shape. Housing 140A can have a width axis equal to width W2 and a length axis equal to L2. In the illustrated example, housing 140A has a rectangular width and length footprint with length L2 being greater than width W2.

First inverter 104A and first transformer 106A can be positioned in close proximity to each other or in contact with each other to fit on first skid 108A. First inverter 104A and first transformer 106A can be mounted to first skid 108A so as to be immobilized. As such, first inverter 104A, first transformer 106A and first skid 108A can be linked together as a single equipment unit. First skid 108A can be made of a rigid material, such as steel, fiberglass, aluminum, polymer and others. As such, the positions of first inverter 104A and first transformer 106A relative to each other can be fixed.

Second inverter 104B, second transformer 106B and second skid 108B can be configured to be the same as first inverter 104A, first transformer 106A and first skid 108A, respectively. As such, lower skid unit 102A and upper skid unit 102B can be equivalents and can be interchangeable. Thus, lower skid unit 102A and upper skid unit 102B can be interchanged such that lower skid unit 102A is positioned above upper skid unit 102B via support structure 110. However, in other examples of the present disclosure, lower skid unit 102A and upper skid unit 102B can be different in that they have one or more differences in size, geometry, shape and electrical characteristics. For example, lower skid unit 102A can be previously installed at the site of a BESS having a first inverting and transforming capability and upper skid unit 102B can be newly installed at the site of lower skid unit 102A and can have a second inverting and transforming capability than lower skid unit 102A, In such an example, the newly installed unit can have greater capabilities than the previously installed unit to accommodate an increase of the number of battery containers at the BESS site.

Support structure 110 can comprise a structure to lift second skid 108A above surface 124. In examples, support structure 110 can be constructed to fit first skid 108A at least partially underneath second skid 108B. Support structure 110 can comprise a support structure for stacking upper skid unit 102B above lower skid unit 102A. Support structure 110 can also provide a structure to allow personnel to access various portions of first skid 108A and second skid 108B, such as panels 132A and 142A, cables 150A 156A, etc. Furthermore, support structure 110 can provide safety features for the protection of personnel from potential dangers of skid unit 102A and skid unit 102B, as well as protection of skid unit 102A and skid unit 102B from the elements and each other. Support structure 110 can be painted or coated and/or fabricated from galvanized steel to prevent corrosion.

Platform 112 can comprise a shelf or body that can support electrical equipment such as inverter 104B and transformer 106B. In examples, platform 112 can be a rigid body. As discussed below, platform 112 can be fabricated from materials and to have thicknesses to mitigate potential harm to personnel engaging upper skid unit 102B. Platform 112 can have dimensions equal to width W4 and length L4. The footprint of platform 112 can be larger than the footprint of upper skid unit 102B to allow space for personnel to interact with upper skid unit 102B.

Posts 114 can be connected to platform 112 to elevate platform 112 relative to surface 124. Posts 114 can comprise elongate bodies of any suitable type, such as posts, columns, beams, tubes and the like. Any suitable number of posts 114 can be used to support the weight of platform 112 and upper skid unit 102B. In examples, posts 114 can comprise metal tubes attached to platform 112 in a fixed manner, such as via fasteners or welding. In examples, posts 114 can have adjustable heights such that support structure 110 can be constructed for different sized electrical equipment. In examples, the position along posts 114 where platform 112 is connected can be adjusted to provide different heights H2. In examples, platform 112 can be connected to the upper tips of posts 114 and different length posts 114 can be used in different constructions for use with different electrical equipment. Height H2 can be selected to provide clearance distance D1 between the tops of first inverter 104A and first transformer 106A and the bottom of platform 112. Clearance distance D1 can be selected to allow heat from inverter 104A and transformer 106A to dissipate and to allow space for raceway 122A and raceway 122B.

Raceways 122A and 122B can be positioned underneath platform 112 to receive cables from inverter 104B and transformer 106B. As can be seen in FIG. 3B, inverter 104A can comprise DC cable 150A, AC cable 152A and communication cable 154A, and transformer 106B can comprise DC cable 156B. Likewise, as can be seen in FIG. 3A, inverter 104B can comprise DC cable 150B, AC cable 152B and communication cable 154B, and transformer 106A can comprise DC cable 156A.

Raceways 122A and 122B can comprise cages or tunnels through which cables and other components can be extended. Raceway 122A can be configured to hold cable 156B. Raceway 122B can be configured to hold cable 150B, 152B and 152B. Raceways 122A and 122B can extend all the way across W4 of platform 112 or only partially as illustrated in FIG. 3A, Raceways 122B and 122A can extend only as far across platform 112 to reach cables 150B 154B and cable 156B, respectively, and extend the cables to the edge of platform 112. Inverter 104B and transformer 106B can comprise bottom-fed units where cables to operate the units extend from the bottom thereof. Cables 150B 154B and cable 156B extend through openings in skid 108B to reach raceways 122A and 122B. Inverter 104A and transformer 106A can additionally comprise bottom-fed units where cables to operate the units extend from the bottom thereof and into and through skid 108A.

Ladder 116 can be attached to platform 112 to allow personnel access to the top of platform 112. Ladder 116 can comprise a pair of side rails connected by a plurality of steps. Cage 118 can be connected to ladder 116 to prevent or inhibit personnel from falling off or otherwise involuntarily separating from ladder 116. Cage 118 can comprise a partial tunnel or tube that connects to the side rails of ladder 116. Cage 118 and ladder 116 can form a full tunnel or tube below platform 112. Cage 118 can extend above platform 112 to open up to the top of platform 112. Railing 120 can extend from cage 118 and can connect to platform 112. In the illustrated example, railing 120 only extends partially along platform 112 to reach inverter 104B and transformer 106B, thereby bordering distance D2 and distance D3 to prevent personnel from falling off or otherwise involuntarily separating from the top of platform 112, In examples, railing 120 can completely surround the perimeter of platform 112 and can have an access point for ladder 116, such as a gate. Railing 120 can comprise structures such as rails, posts, slats, pickets, lattice structures and the like to form barriers. Platform 112 can also include toe plates that can prevent feet of personnel from slipping over the edge of platform 112. The toe plates can be integrated into railing 120.

Inverter 104A, transformer 106A and skid 108A of lower skid unit 102A can be configured to have maximum height III, maximum length L3 and maximum width W3 for a particular combination of inverter, transformer and skid used at a specific installation. In examples, height H1 can be over seven feet (˜2.1 meters) tall. Likewise, inverter 104B, transformer 106B and skid 108B of upper skid unit 102B can be configured to have a maximum height, maximum length and maximum width, which can be the same or different as lower skid unit 102A. Support structure 110 can be specifically constructed to position upper skid unit 102B relative to lower skid unit 102A, as discussed herein, to provide access features and safety features in a geometrically compact space. Although the present disclosure is described with reference to inverter 104A and transformer 106A having W1 that can equal W2, different sized components can be used. For example, W1 and W2 can be the same in instances where inverter 104A an transformer 106A are produced as coupled devices by the same manufacturer. However, inverter 104A and transformer 106A can be from different manufacturers and can have different dimensions. Likewise, platform 106A need not match the exact footprint of inverter 104A and transformer 106A and can be sized accordingly to support inverters 104A and transformers 106A of different sizes.

Skid 108A and support structure 110 can be positioned on surface 124. Skid 108B can be positioned on platform 112. A portion of width W4 comprising distance D2 can be unoccupied by inverter 104B and transformer 106B. A portion of length L4 comprising distance D3 can be unoccupied by inverter 104B and transformer 106B. The extra lengths of platform 112 provided by distances 132 and D3 can be used to provide access to inverter 104B and transformer 106B on top of platform 112. For example, distance D2 can allow access panels 132B and 142B to open in a location where personnel can be located. Additionally, distance D2 can be used to allow inverter 104B and transformer 106B to be laterally offset from inverter 104A and transformer 106A in order allow for access to the bottom of inverter 104B and transformer 106B and the sides of inverter 104A and transformer 106A. The offsets provided by distance D2 and distance D3 can remain small enough that stacked skids unit 100 can fit within the footprint of one of electrical equipment skids 54A-54H of FIG. 2B such that footprint 48 need not be expanded. Thus, the offsets provided by distance D2 and distance D3 can encroach on the aisles provided between electrical equipment skids 54A-54H and BESS containers 52A 52H, but still leave the aisles large enough to allow personnel and equipment to pass through.

Lower skid unit 102A and upper skid unit 102B can be rotated one-hundred-eighty-degrees relative to each other relative to a horizontal plane. Such an arrangement can facilitate access to panels 132A and 142A, etc. Personnel can stand underneath platform 112 adjacent inverter 104A and transformer 106A to access panels 132A and 142A. Personnel can stand on top of platform 112 adjacent inverter 104B and transformer 106B to access panels 132B and 142B. If lower skid unit 102A and upper skid unit 102B were not offset and platform 112 were sized generally equally to the footprint of inverter 104B and transformer 106B, there would not be sufficient space for personnel to access panels 132B and 142B. Likewise, if lower skid unit 102A and upper skid unit 102B were not offset and platform 112 were sized generally equally to the footprint of inverter 104B and transformer 106B, there would not be sufficient space for personnel to access the underside of inverter 104B and transformer 106B.

The longitudinal spacing of distance D1 between inverter 104A and transformer 106A and inverter 104B and transformer 106B can allow for 1) heat dissipation from inverter 104A and transformer 106A and 2) arc flash mitigation between electrical equipment. Distance D1 can be based on clearance recommendations from manufactures of inverter 104A and transformer 106A. Typically, inverters have larger clearance requirements than transformers.

Furthermore, platform 112 can be fabricated to minimize effects of a potential arc flash event and to absorb and redirect energy from a blowout panel being released. For example, platform 112 can be fabricated from a concrete slab reinforced with steel bars or from steel plating. Platform 112 can be configured to not have any openings extending therethrough, such as are included in grating, to minimize arc flash and blowout panel energy passing therethrough.

One-hundred-eighty-degree rotation of upper skid unit 102B relative to lower skid unit 102A can help mitigate condensation. For example, inverters 104A and 104B can be designed to produce convection heat from the top surface. Thus, heat from inverter 104A can heat platform 112 to prevent the formation of condensation, which can comprise a safety hazard for personnel standing on platform 112.

Additionally, the one-hundred-eighty-degree rotation of upper skid unit 102B relative to lower skid unit 102A can help prevent heat damage to inverter 104B. Inverters can produce more heat than transformers. Inverter 104B will already be producing its own heat such that placing inverter 104B in the heat stream of inverter 104A could produce undesirable heating of inverter 104B. Thus, transformer 106B is more able to accommodate heat from inverter 104A, Additionally, the solid construction of platform 112 discussed herein can prevent heat from inverter 104A and transformer 106A from reaching inverter 104B and transformer 106B.

In examples, the teachings of the present disclosure can be used to upgrade an existing stationary energy storage system, such as a BESS, already installed at a site. For example, BESS 46 of FIG. 2A can be upgraded to BESS 46 of FIG. 2B. Thus, a sub-set of existing or previously installed electric equipment skids 54A-54G can be removed from their installed locations at BESS 46 to clear open space at BESS. New BESS containers compatible with BESS containers 52A-52H can be installed at the newly cleared open spaces. The new BESS containers can be equivalents of BESS containers 52A-52H or can be different, such as by having greater energy storage capacity. A support structure, such as support structure 110, can be built around one or more of already installed electric equipment skids 54A-54G that have not been removed. In examples, the removed electrical equipment skids of electric equipment skids 54A-54G can be repositioned on the support structure, particularly if the newly installed BESS containers are equivalents of BESS containers 52A-52H. In examples, new, not previously installed electrical equipment skids can be positioned on the support structure, such as those having inverters and transformers with the capability to operate with BESS containers having greater energy storage capacity that BESS containers 52A-52H.

### VARIOUS NOTES

The above detailed description includes references to the accompanying drawings, which form a part of the detailed description. The drawings show, by way of illustration, specific embodiments in which the invention can be practiced. These embodiments are also referred to herein as “examples,” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and 13,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 CFR. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A battery energy storage system (BESS) comprising:
a first equipment unit comprising:
a first skid configured to be positioned on a surface;
a first inverter mounted on the first skid; and
a first transformer mounted on the first skid;
a second equipment unit comprising:
a second skid;
a second inverter mounted on the second skid; and
a second transformer mounted on the second skid; and
a support structure for positioning the second equipment unit longitudinally above and spaced apart from the first equipment unit in a laterally offset manner.

2. The BESS of claim 1; wherein:
the first equipment unit and the second equipment unit are functionally and structurally interchangeable; and
the first equipment unit and the second equipment unit are rotated opposite each other relative to a horizontal plane such that the first inverter is at least partially under the second transformer and the first transformer is at least partially under the second inverter.

3. The BESS of claim 2, wherein:
outer dimensions of the first equipment unit are defined by first outer housings for the first inverter and the first transformer;
outer dimensions of the second equipment unit are defined by second outer housing for the second inverter and the second transformer;
access panels in the first outer housings for the first equipment unit are positioned under the second equipment unit; and
access panels in the second outer housings for the second equipment unit are positioned above the first equipment unit.

4. The BESS of claim 3, wherein the first inverter comprises a blowout panel located on a top surface of the first inverter, the blowout panel positioned at least partially under the second transformer.

5. The BESS of claim 2, wherein:
each of the first inverter and the second inverter have a first rectangular footprint comprising:
a first axis length and a second axis length; and
each of the first transformer and the second transformer have a second rectangular footprint comprising:
a third axis length and a fourth axis length;
wherein:
the first axis length and the third axis length are approximately equal; and
the second axis length and the fourth axis length are together greater than the first axis length and the third axis length together.

6. The BESS of claim 1; wherein the support structure comprises:
a platform upon which the second inverter and the second transformer are positioned; and
a plurality of posts connected to the platform configured to elevate the platform above the surface.

7. The BESS of claim 6, wherein:
the platform has a length greater than a combined length of the second inverter and the second transformer; and
the platform has a width greater that a combined width of the second inverter and the second transformer.

8. The BESS of claim 7, further comprising a first cable raceway positioned underneath the platform.

9. The BESS of claim 8, wherein the second inverter and the second transformer comprise cables extending from undersides of the second inverter and the second transformer.

10. The BESS of claim 9, wherein the second skid includes internal passageways to allow for passage of at least some of the cables through the second skid.

11. The BESS of claim 8, wherein the first cable raceway extends in a lateral direction.

12. The BESS of claim 8, further comprising a second cable raceway;
wherein:
the first cable raceway is positioned underneath the platform below the second inverter; and
the second cable raceway is positioned underneath the platform below the second transformer.

13. The BESS of claim 6, wherein the platform comprises a solid structure configured to mitigate arc flash hazard.

14. The BESS of claim 13, wherein the platform is fabricated at least partially from concrete or steel plate.

15. The BESS of claim 6, further comprising:
a ladder extending downward from the platform; and
a cage at least partially surrounding the ladder.

16. The BESS of claim 6, further comprising a railing and a toe plate at least partially surrounding the platform.

17. The BESS of claim 6, wherein the plurality of posts allow access to all sides of the first equipment unit.

18. A method of increasing energy storage capacity of a Battery Energy Storage System (BESS), the method comprising:
building a support structure over a first inverter and transformer unit installed at a first location of the BESS;
placing a second inverter and transformer unit on the support structure such that the second inverter and transformer unit is longitudinally spaced from and laterally offset from the first inverter and transformer unit; and
adding an additional battery container to the BESS.

19. The method of claim 18, further comprising
removing the second inverter and transformer unit from a second location of the BESS; and
positioning the additional battery container at the second location.

20. The method of claim 18, further comprising building the support structure to have a solid platform constructed of concrete or steel plate to provide arc flash protection between the first inverter and transformer unit and the second inverter and transformer unit.
